(19) United States
(12) Patent Application Publication
(10) Pub. No.: US 2014/0247564 A1
(43) Pub. Date: Sep. 4, 2014

(54) SHIELDING STRUCTURE FOR ELECTRONIC DEVICE

(71) Applicants: Jiwei Shi, Beijing (CN); Yingjie Hu, Beijing (CN); WenXin Huang, Beijing (CN)

(72) Inventors: Jiwei Shi, Beijing (CN); Yingjie Hu, Beijing (CN); WenXin Huang, Beijing (CN)

(73) Assignee: THOMSON LICENSING a corporation

(21) Appl. No.: 14/351,887

(22) PCT Filed: Oct. 31, 2011
(86) PCT No.: PCT/CN2011/081585

§ 371 Date: Apr. 15, 2014

(51) Int. Cl. H05K 9/00; H05K 7/20

(52) U.S. Cl. CPC H05K 9/0022; H05K 7/20418; H05K 7/20427; H05K 2007/204
USPC 361/720; 174/350

(57) ABSTRACT

The invention provides an electromagnetic shielding for electronic device. The electromagnetic shielding comprises: an opening provided at a position corresponding to the electronic device, through which a heat sink passes to be in contact directly with the electronic device; and at least one elastic arm made of conductive material provided at the circumference of the opening which are extending in a direction away from the shielding to be in a conductive contact with the side surface of the heat sink when the heat sink is mounted in position.

### TECHNICAL FIELD

The present invention relates to a shielding structure for electronic device.

### BACKGROUND

It should be noted that this section is intended to introduce various aspects of art to the reader, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

In an electronic device, some electrical or optical components can generate electromagnetic interference (EMI), which interrupts the normal operation of other components. In addition, if electrostatic energy generated is not discharged to ground, the components of the electronic device might be damaged. Therefore, conventionally the electronic device will have an electromagnetic compliant (EMC) shielding with an ESD (Electrostatic Discharge) functionality to enclose the electrical or optical components.

Heat generated during operation of the electrical or optical components will also heat up the components, in which case the failure of components might be caused. So normally a heat sink is needed to dissipate heat to the external environment.

FIG. 1 is an exemplary diagram showing a conventional shielding structure of an electronic device with EMC and heat sink functionalities.

As shown in FIG. 1, a plurality of electrical or optical components of the electronic device are generally indicated by the reference number 101. The electrical or optical components 101 are attached to a printed circuit board (PCB) 102. The electronic device also comprises a shielding 103 enclosing the electrical or optical components 101 on the PCB 102 to provide an EMC functionality. In FIG. 1, a heat sink 104 is placed on the shielding 103 to be in contact with the shielding 103 for dissipating heat generated by the electrical or optical components 101 to the external environment. Due to the machining and fit tolerances, there will be a gap between the shielding 103 and the surface of electrical or optical components 101, which will lead to a lower thermal transfer efficiency between the shielding 103 and the electrical or optical components 101. It could be appreciated that, since the heat sink 104 is not in contact directly with the electrical or optical components 101 to be cooled, the radiating efficiency of the heat sink 104 will depend largely on the above thermal transfer efficiency. In view of the above problem, an additional thermal conductive material 105 is provided between the electrical or optical components 101 and the shielding 103 to improve the thermal transfer efficiency. The introduction of the additional thermal conductive material along with relevant manufacture process increases the cost of the shielding structure.

Accordingly, there is a need for a low-cost shielding structure with EMC and heat sink functionalities.

### SUMMARY

According one aspect of the invention, an electromagnetic shielding for electronic device is provided. The electromagnetic shielding comprises: an opening provided at a position corresponding to the electronic device, through which a heat sink passes to be in contact directly with the electronic device; and at least one elastic arm made of conductive material provided at the circumference of the opening which are extending in a direction away from the shielding to be in a conductive contact with the side surface of the heat sink when the heat sink is mounted in position.

According one aspect of the invention, an electronic device is provided. The electronic device comprises a printed circuit board to which an electrical component is attached, an electromagnetic shielding according to one of the previous claims for shielding said component, wherein the opening is positioned over the component, and a heat sink placed on the component, wherein the heat sink is positioned in the opening.

It is to be understood that more aspects and advantages of the invention will be found in the following detailed description of the present invention.

### BRIEF DESCRIPTION OF THE DRAWINGS

The accompanying drawings are included to provide further understanding of the embodiments of the invention together with the description which serves to explain the principle of the embodiments. The invention is not limited to the embodiments.

In the drawings:

FIG. 1 is an exemplary diagram showing a conventional shielding structure of an electronic device with EMC and heat sink functionalities;

FIG. 2 is an exemplary diagram showing a shielding structure of an electronic device with EMC and heat sink functionalities according to an embodiment of the present invention;

FIG. 3 is an exemplary diagram showing a structure of the spring arms on the shielding according to an embodiment of the present invention; and

FIG. 4 is an exemplary diagram in perspective view showing a shielding structure of an electronic device with EMC and heat sink functionalities with the heat sink assembled according to an embodiment of the present invention; and

FIG. 5 is an exemplary diagram in perspective view showing a shielding structure of an electronic device with EMC and heat sink functionalities with the heat sink removed according to an embodiment of the present invention.

### DETAILED DESCRIPTION

An embodiment of the present invention will now be described in detail in conjunction with the drawings. In the following description, some detailed descriptions of known functions and configurations may be omitted for conciseness.

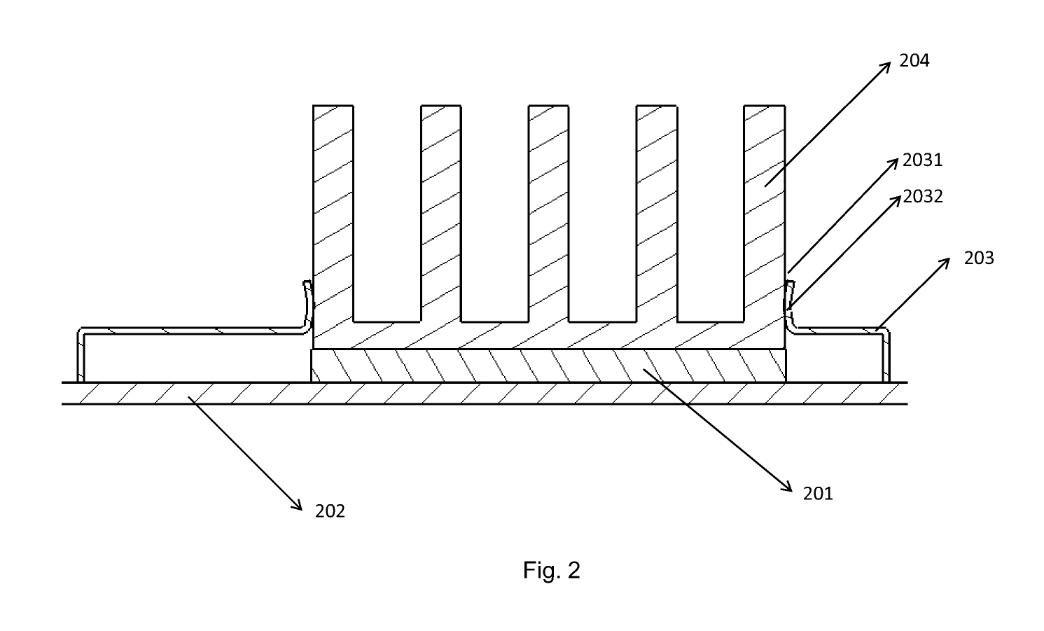

FIG. 2 is an exemplary diagram showing a shielding structure of an electronic device with ESD and heat sink functionalities according to an embodiment of the present invention.

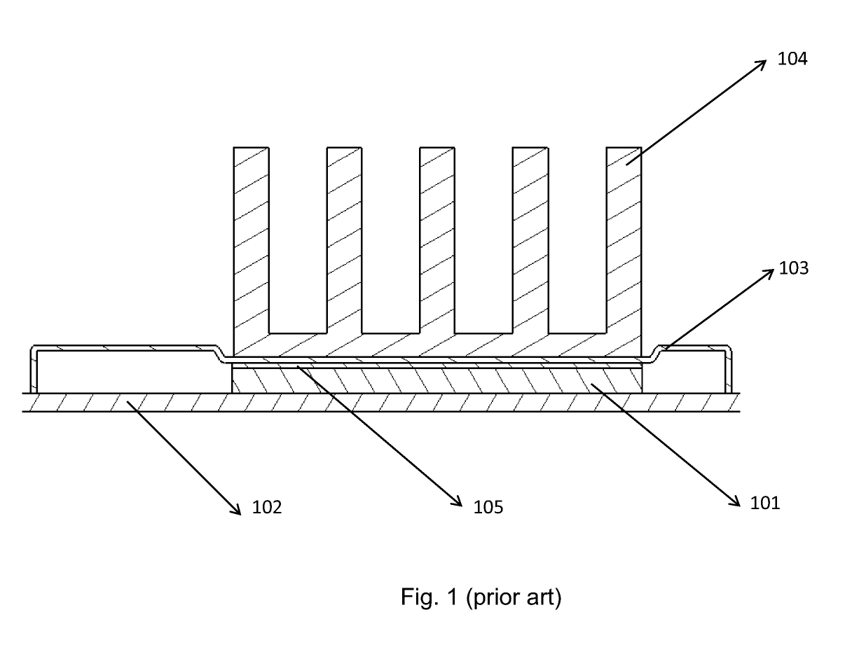

The electronic device 200 in FIG. 2, similar to that in FIG. 1 described above, comprises a plurality of electrical or optical components, which are generally indicated by the reference number 201. The electrical or optical components 201 are attached to a PCB 202.

As shown in FIG. 2, the electronic device 200 comprises a shielding 203 enclosing the electrical or optical components 201 on the PCB 202 to provide an EMC functionality. For example, the shielding 203 can be mounted onto the PCB 202 by soldering, which could ensure the shielding 203 to have a conductive contact with a grounding pad (not shown) on the PCB 202. According to the embodiment of the invention, the shielding 203 is provided with an opening 2031 at a position corresponding to the electrical or optical components 201, through which a heat sink 204 can pass to be contacting directly with the electrical or optical components 201. Preferably, as shown in the embodiment of FIG. 2, the shape and the dimension of the opening 2031 are substantially identical to the outline shape and the dimension of the cross section of the heat sink 204 respectively, with tolerance to allow the heat sink 204 to pass through. In many cases the heat sink 204 has a rectangular cross section for purpose of reducing the manufacturing cost. Therefore, the embodiment of the invention will be described taking a heat sink with rectangular cross section as an example for illustrative purpose. But it could be appreciated that a heat sink with other shapes can also be used. The heat sink 204 can be mounted onto the PCB 202 by a fastener with springs or levers which could contribute a downward press. It could be appreciated that, since the heat sink 204 could be in direct contacts with the components 201 to be cooled in this embodiment, the thermal transfer efficiency will be improved.

As shown in FIG. 2, at least one elastic arm 2032 is provided at the circumference of the opening 2031, which are extending in a direction away from the shielding 203. The elastic arm 2032 is made of conductive material having elasticity, for example, stainless steel. The elastic arm 2032 will be in contact with the side surface of the heat sink 204 when the heat sink 204 is mounted in position to form a complete EMC shielding structure for the electrical or optical components 201. The heat sink forms an integral part of the shielding. It could be appreciated that more elastic arms 2032 can be provided if needed. For example, the elastic arms 2032 can be provided in pairs, in which case each pair can be provided at a symmetrical position of the circumference of the opening 2031. Certainly, the four sides of the rectangular opening 2031 can all be provided with a elastic arm 2032 respectively, that is, there will be four elastic arms in total. In addition, in all cases each elastic arm 2032 can occupy the whole or part of the side of the rectangular opening 2031.

In the embodiment of FIG. 2, since the shape and the dimension of the opening 2031 are substantially identical to the outline shape and the dimension of the cross section of the heat sink 204 respectively, each elastic arm 2032 extends in substantially perpendicular direction to the surface of the shielding 203 in a direction away from the shielding 203.

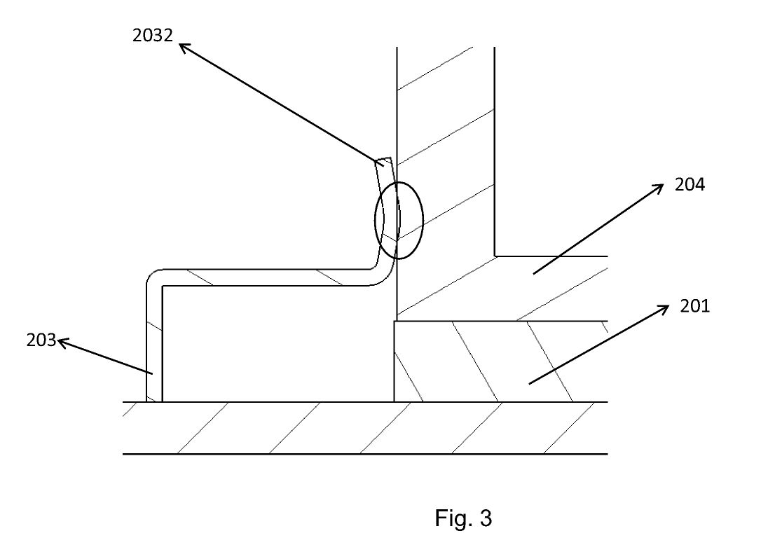

FIG. 3 is an exemplary diagram showing a structure of one spring arm on the shielding according to an embodiment of the present invention. As shown in FIG. 3, a guide chamfer or bending is provided on the elastic arm 2032 to facilitate the mounting of the heat sink 204 through the opening 2031. It can be appreciated that generally the heat sink 204 is made of conductive metal material, such as aluminum. Additionally, in most cases the heat sink 204 will have a conductive oxidation coating for purpose of corrosion resistance. Therefore, when the heat sink is mounted, there will be an elastic deformation generated on a part of the elastic arms 2032 indicated by the circle in FIG. 3, which brings a clamp force to the heat sink 204 to ensure a conductive contact between the elastic arms 2032 and corresponding side surfaces of the heat sink 204. Because of the conductive contact between the elastic arms 2032 and corresponding side surfaces of the heat sink 204 and that between the heat sink 204 and the grounding pad of the PCB 202, a completed EMC shielding structure is formed by the shielding 203, the heat sink 204 and the grounding pad on the PCB 202, which will prevent the electrical or optical components 201 from electromagnetic interferences by other components outside the shielding 203.

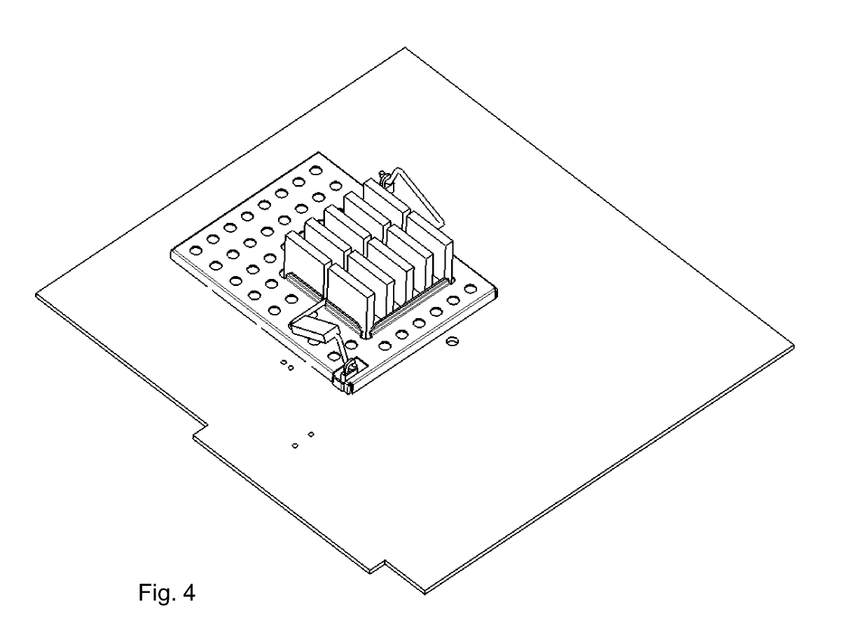

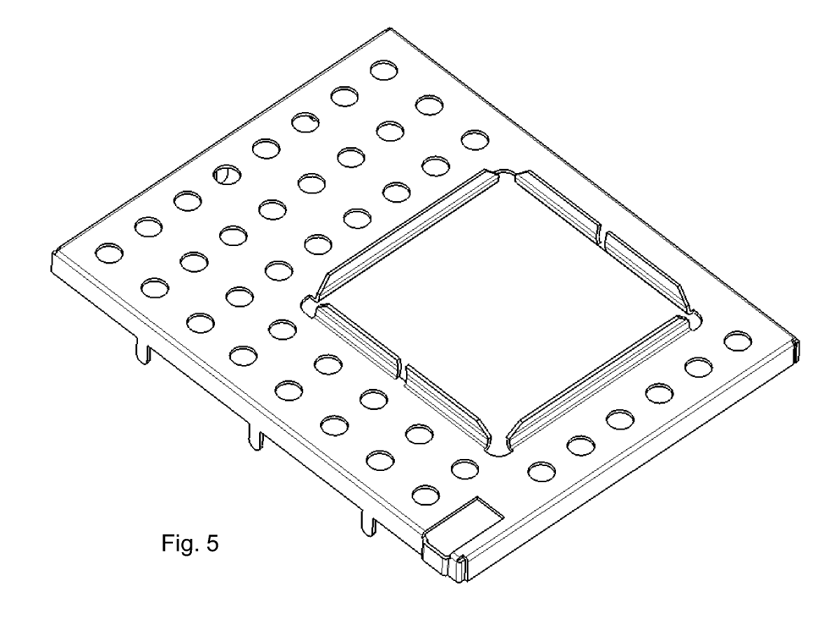

FIG. 4 is an exemplary diagram in perspective view showing a shielding structure of an electronic device with EMC and heat sink functionalities according to an embodiment of the present invention. FIG. 5 is an exemplary diagram in perspective view showing a shielding structure of an electronic device with EMC and heat sink functionalities with the heat sink removed according to an embodiment of the present invention. As shown in FIGS. 4 and 5, a shielding structure for an electric device, a CPU on a PCB in this case, is provided. A shielding is provided with a rectangular opening which allows a heat sink to pass through and contact directly with the CPU on the PCB. Four elastic arms, provided at each side the circumference of the opening, extend in a direction away from the shielding to be contacting with respective surfaces of the heat sink. Each elastic arm occupies the whole side of the opening (two elastic arms have a small notch allowing other elements to pass through). According to the embodiment of the invention, since the heat sink is contacting directly with the CPU on the PCB, the thermal transfer efficiency will be improved. In addition, because of the elastic arms provided on the shielding, a completed shielding structure is formed to achieve an EMC functionality. Therefore, a low-cost shielding structure with good heat transfer efficiency and an adequate EMC functionality is provided.

1. An electromagnetic shielding for electronic device, comprising:
an opening provided at a position corresponding to the electronic device, through which a heat sink passes to be in contact directly with the electronic device; and
at least one elastic arm made of conductive material provided at the circumference of the opening, which are extending in a direction away from the shielding to be in a conductive contact with the side surface of the heat sink when the heat sink is mounted in position.

2. The electromagnetic shielding for electronic device according to the claim 1, wherein the shape and the dimension of the opening are substantially identical to the outline shape and the dimension of the cross section of the heat sink respectively, with the purpose of positioning the heat sink in the opening.

3. The electromagnetic shielding for electronic device according to the claim 1, wherein elastic arms are provided in pairs.

4. The electromagnetic shielding for electronic device according to the claim 3, wherein each pair of elastic arms are provided at symmetrical position of the circumference of the opening.

5. The electromagnetic shielding for electronic device according to claim 1, wherein the elastic arm is made of stainless steel.

6. The electromagnetic shielding for electronic device according the claim 2, wherein a guide chamfer or bending is provided on the elastic arm to facilitate the mounting of the heat sink through the opening.

7. The electromagnetic shielding for electronic device according to claim 1, wherein the heat sink is provided with a conductive coating.

8. The electromagnetic shielding for electronic device according to the claim 7, wherein the conductive coating is a conductive oxidation coating.

9. The electromagnetic shielding for electronic device according to claim 1, wherein both the shielding and the electronic device are mounted on a printed circuit board.

10. An electronic device comprising a printed circuit board to which an electrical component is attached, an electromagnetic shielding according to one of the previous claims for shielding said component, wherein the opening is positioned over the component, and a heat sink placed on the component, wherein the heat sink is positioned in the opening.
